(19) United States
(12) Patent Application Publication
(10) Pub. No.: US 2022/0281203 A1
(43) Pub. Date: Sep. 8, 2022

(54) THIN ENCAPSULATING ATTACHMENT STRUCTURE

(71) Applicant: G2F Tech Co., Ltd., Taipei City (TW)

(72) Inventor: Jie-Qi LU, Taipei City (TW)

(21) Appl. No.: 17/353,085

(22) Filed: Jun. 21, 2021

(30) Foreign Application Priority Data
Mar. 4, 2021 (TW) 110107799

(51) Int. Cl. B32B 3/04; B32B 3/26; B32B 7/12

(52) U.S. Cl. CPC B32B 3/04; B32B 3/26; B32B 7/12; B32B 2307/302; B32B 2457/00

(57) ABSTRACT

A thin encapsulating attachment structure, consisting of a first thin film portion, which is provided with two surfaces, wherein one of the surfaces is partially or completely contiguously attached to an attachment portion; and a second thin film portion, which is provided with two surfaces, wherein one of the surfaces is partially or completely contiguously attached to the attachment portion. The attachment portion, which is positioned between the first thin film portion and the second thin film portion, and is a binding agent composed of at least an epoxy resin, a silicone resin, polyester, polyurethane, nano silicate, or a nano titanium, the thickness range of the attachment portion is 0.5˜100 micrometers. The first thin film portion, the attachment portion, and the second thin film portion are assembled to form the thin encapsulating attachment structure, the thickness of which is less than or equal to 200 micrometers.

### BACKGROUND OF THE INVENTION

### (a) Field of the Invention

The present utility model relates to a thin film structures that has application in vaporization and heat dissipation for electronic components.

### (b) Description of the Prior Art

At present, thin vapor chambers are regarded as the preferred heat dissipation solution for 5G high transmission chips. A traditional thin vapor chamber uses internal evaporation and condensation phenomena to passively transfer heat from the chips to the entire vapor chamber. In order to enable widespread use in 5G electronic equipment, the problems of manufacturing costs and mass production of traditional thin vapor chambers are still waiting to be resolved. Current attachment technology for thin vapor chambers includes diffusion attachment, laser welding, and eutectic attachment. However, such attachment technology for ultra thin vapor chambers creates limitations such as a complicated manufacturing process, low production efficiency, and high manufacturing costs.

As for research in the prior art regarding portable electronic devices without an injection tube that use a thin film vapor chamber and manufacturing method thereof, Taiwan Patent No. TW108140361 discloses a structure comprising: a lower plate, the upper surface of which has a plurality of protruding portions formed thereon, a plurality of first protrusions are formed on one side of the upper surface thereof that are separated at predetermined intervals and protrude therefrom, and a first attachment body is formed protruding from the outer side edge at a predetermined distance following the edge and turning upward toward the inner side; and an upper plate, a second attachment body is protrudingly formed thereon that attaches to the upper side of the lower plate, and a working fluid is injected into the interior through an injection opening formed within second protrusions protrudingly formed on the upper plate corresponding to the first protrusions. When the lower plate is flexed and contacts the injection opening, the injection opening is sealed by a step protrudingly formed downward towards the lower side. A vacuum injection device is tightly attached to the injection opening of the upper plate, which is in an attachment configuration with the lower plate, whereby the internal space formed between the upper plate and the lower plate is in a vacuum state, the working fluid is then injected into the internal space.

As for research in the prior art regarding smart phone integral body vapor chambers, Taiwan Patent No. TW108140413 discloses a smart phone integrated vapor chamber, which is enables the integrated manufacturing of a smart phone frame without changing the thickness thereof. An assembly portion formed in the smart phone frame enables a vapor chamber to be correspondingly assembled therein. In order to readily achieve a tightening effect therebetween, a short protruding edge is respectively formed on the outer edge of the assembly portion and the vapor chamber. In addition, holes and protrusions are further respectively formed on the short protruding edges to increase the tightening force therebetween. Moreover, the smart phone integrated vapor chamber can also be applied in a structure whereby smart phone frame is integratedly joined to a vapor chamber and a structure whereby the smart phone itself is formed with a vapor chamber.

As for research in the prior art regarding heat dissipation devices, Taiwan Patent No. TW108147553 discloses a heat dissipating device that is able to bring into effect excellent cooling characteristics for high heat generating components mounted in a narrow space. The heat dissipation device comprises a plurality of heat pipes, which are thermally connected to the heat generating components; and a heat dissipation portion, which is thermally connected to the plurality of heat pipes. Further, at least evaporation portions of the plurality of heat pipes are thermally connected to the heat generating components, wherein the cross-section shape of the orthogonal heat transmission direction of the plurality of heat pipes provided with the evaporation portions is a flat oval portion. Moreover, the surface thickness direction of the flat oval portions is in the opposite direction to the heat generating components.

### SUMMARY OF THE INVENTION

The present utility model provides a thin encapsulating attachment structure, comprising: a first thin film portion, which is provided with two surfaces, wherein one of the surfaces is partially or completely contiguously attached to an attachment portion; the attachment portion, which is positioned between the first thin film portion and a second thin film portion, wherein the attachment portion is a binding agent composed of at least an epoxy resin, silicone resin, polyester, polyurethane, nano silicate, or nano titanium, and the thickness range of the attachment portion is 0.5˜100 micrometers; and the second thin film portion, which is provided with two surfaces, wherein one of the surfaces is partially or completely contiguously attached to the attachment portion. The present invention has characteristics including the first thin film portion, the attachment portion, and the second thin film portion are assembled to form the thin encapsulating attachment structure, the thickness of which is less than or equal to 200 micrometers. The first thin film portion is aluminum, copper, nickel, gold, silver, silicon, ceramic, epoxy resin, polyimide, or plastic. A 90-degree peel strength of the attachment portion attached between the first thin film portion and the second thin film portion is ≥4 N/cm. A 180-degree peel strength of the attachment portion attached between the first thin film portion and the second thin film portion is≥2 N/cm. The second thin film portion is aluminum, copper, nickel, gold, silver, silicon, ceramic, epoxy resin, polyimide, or plastic. At least the first thin film portion and the second thin film portion is internally provided with a holding space, which is filled with at least a gel, wax, hot-melt material, or a heat conduction material. The heat conduction material internally contains at least aluminum oxide, aluminium nitride, boron nitride, carborundum, carbon black powder, graphite powder, graphene powder, carbon nanotubes, nano diamond powder, or ceramic powder. The holding space enables holding electronic chip components, to enable covering the electronic chip components. Furthermore, the thin encapsulating attachment structure comprises at least the first thin film portion and the second thin film portion, and the outer side surface of the first thin film portion is further covered with at least a first functional layer, the thickness of which is less than 200 micrometers; moreover, the lower surface of the first functional layer is laminated adjacent to the upper surface of the first thin film portion. The first functional layer is a ceramic material, graphene material, or a binding agent, wherein the binding agent is composed of at least an epoxy resin, silicone resin, polyester, polyurethane, nano silicate, or nano titanium. The present embodiment further comprises at least one layer of a second functional layer, the thickness of which is less than 200 micrometers, with the lower surface of the second functional layer laminated adjacent to the upper surface of the first functional layer. The second functional layer is a ceramic material, graphene material, binding agent, polyimide, polyamide, polyester, polypropylene, polyurethane, copper, aluminum, glue material, or a metal conducting material, wherein the binding agent is composed of at least an epoxy resin, a silicone resin, polyester, polyurethane, nano silicate, or nano titanium. In addition, the thin encapsulating attachment structure further comprises at least the first thin film portion and the outer side surface of the second thin film portion is further covered with a heat dissipation coating, which is at least graphene, graphite flakes, or ceramic. The present utility model provides a thin encapsulating attachment structure with more advanced specifications, wherein the thickness of the thin encapsulating attachment structure is less than or equal to 200 micrometers, and such a thin structure distinguishes and differentiates it from the prior art, providing a solution to heat dissipation of electronic equipment within increasingly small space constraints. Hence, the originality, advancement, and practical effectiveness of the present invention are unmistakable.

To enable a further understanding of said objectives, structures, characteristics, and effects, as well as the technology and methods used in the present invention and effects achieved, a brief description of the drawings is provided below followed by a detailed description of the preferred embodiments.

### BRIEF DESCRIPTION OF THE DRAWINGS

FIG. 1 is a cross-sectional view of a thin encapsulating attachment structure of the present invention.

FIG. 2 is a cross-sectional view of another embodiment of the thin encapsulating attachment structure of the present invention.

FIG. 3 is a cross-sectional view of the thin encapsulating attachment structure laminated with a first functional layer and second functional layers according to the present invention.

FIG. 4 is a cross-sectional view of a heat dissipation coating deposited on the outer layer of the thin encapsulating attachment structure of the present invention.

### DETAILED DESCRIPTION OF THE PREFERRED EMBODIMENTS

The following description uses specific concrete examples to describe the embodiment modes of the present invention. Persons skilled in the related art can easily deduce other advantages and effects of the present invention from the content disclosed in the specification. The present invention can also use other different concrete embodiments to clarify its performance and applications. Each detail described in the specification can also be based on a different perspective and application, enabling various types of modifications and alterations to be carried out without deviating from the spirit of the present invention.

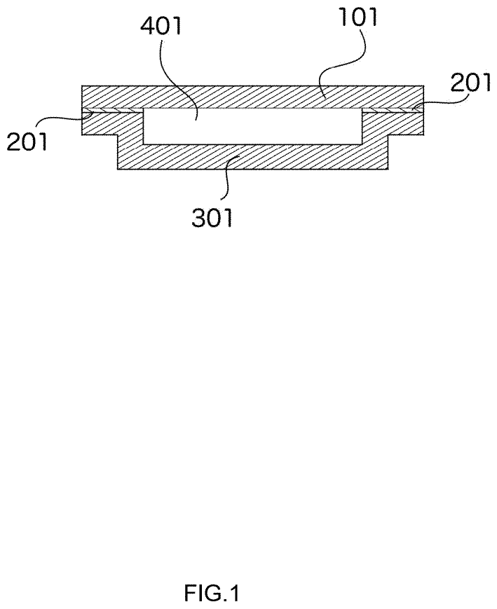

Referring first to FIG. 1, which shows a cross-sectional view of a thin encapsulating attachment structure of the present invention, wherein the present utility model is a thin encapsulating attachment structure comprising: a first thin film portion 101, which is provided with two surfaces, wherein one of the surfaces is partially or completely contiguously attached to an attachment portion 201; the attachment portion 201, which is positioned between the first thin film portion 101 and a second thin film portion 301, wherein the attachment portion 201 is a binding agent composed of at least an epoxy resin, silicone resin, polyester, polyurethane, nano silicate, or nano titanium, and the thickness range of the attachment portion 201 is 0.5˜100 micrometers; and the second thin film portion 301, which is provided with two surfaces, wherein one of the surfaces is partially or completely contiguously attached to the attachment portion 201. The epoxy resin is structurally provided with an epoxide group resin, the most commonly used epoxy resin being a bisphenol A epoxy resin. After undergoing a hardening reaction, the epoxy resin forms a three-dimensional crosslinked polymer network structure. The silicone resin is provided with highly crosslinked structure thermosetting polysiloxane polymers, wherein the polysiloxane polymers are produced from organochlorosilane that has undergone hydrolytic condensation and rearrangement; stable active siloxane prepolymers are then produced under room temperature conditions, and further heating enables contraction and crosslinking to form a relatively hard or flexible, relatively small solid silicone resin. The silicone resin is provided with excellent electrical insulating properties, temperature resistance, and waterproof properties. The main chain of the polyester contains ester (COO) functional group polymers, such as polyethylene terephthalate, and the main chain of the polyurethane contains carbamic ester functional group polymers. The nano silicate and the nano titanium are the admixtures in the above-described polymers to enable increasing adhesion strength thereof. The present invention has characteristics including the first thin film portion 101, the attachment portion 201, and the second thin film portion 301 are assembled to form the thin encapsulating attachment structure; the thickness of which is less than or equal to 200 micrometers, providing a thin vapor chamber (VC) application. At least the first thin film portion 101 and the second thin film portion 301 is internally provided with a holding space 401, which is filled with at least a gel, wax, hot-melt material, or a heat conduction material. The heat conduction material internally contains at least aluminum oxide, aluminium nitride, boron nitride, carborundum, carbon black powder, graphite powder, graphene powder, carbon nanotubes, nano diamond powder, or ceramic powder. The filling material provides vaporizing and heat dissipation functions, which differs from traditional thin vapor chambers not filled to capacity with heat dissipation liquid.

The present invention is not injected with liquid, which resolves the problem of the shortcoming in fluid heat transfer of traditional thin vapor chambers. The gel is a solid, jelly-like material, which is a substantially diluted crosslinked system, and under a stable state has no fluidity. As for weight, the main constituent of the gel is liquid; however, because of the three-dimensional crosslinked network in the gel, in many aspects the gel has characteristics resembling a solid. The wax is an organic compound with long alkane chains, such as fatty acids and esters formed from long-chain alcohols or long chain hydrocarbons. The hot-melt material is a phase change material (PCM), that is, a substance that changes shape as the temperature changes, as well as being able to provide latent heat. The material changing from a solid state to a liquid state or from a liquid state to a solid state is called a phase change process. In addition, as for the electronic encapsulation application aspect of the present invention, the holding space 401 enables holding electronic chip components, to allow coating the electronic chip components. The first thin film portion 101 is aluminum, copper, nickel, gold, silver, silicon, ceramic, epoxy resin, polyimide, or plastic. A 90-degree peel strength of the attachment portion 201 attached between the first thin film portion 101 and the second thin film portion 301 is ≥4 N/cm. A 180-degree peel strength of the attachment portion 201 attached between the first thin film portion 101 and the second thin film portion 301 is ≥2 N/cm. The second thin film portion 301 is aluminum, copper, nickel, gold, silver, silicon, ceramic, epoxy resin, polyimide, or plastic, wherein polyimides can be separated into fatty acids, semi-aromatic series, and aromatic series polyimides according to the functional groups thereof; moreover, polyimides can be separated into thermoplastics and thermoset polyimides according to thermal properties. The polyimide is an organic polymer material containing imide groups, preparation method of which is primarily from a polymerization reaction between diamines and dianhydrides to form a polyamic acid polymer, after which, the polyimide polymer is formed through high temperature imidization.

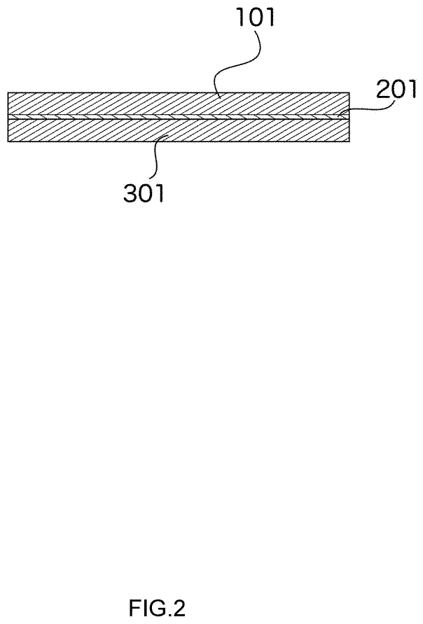

FIG. 2 is a cross-sectional view of another embodiment of the thin encapsulating attachment structure of the present invention, wherein the present utility model is the thin encapsulating attachment structure, comprising: the first thin film portion 101, which is provided with two surfaces, wherein one of the surfaces is partially or completely contiguously attached to the attachment portion 201; the attachment portion 201, which is positioned between the first thin film portion 101 and the second thin film portion 301, the attachment portion 201 is a binding agent made from at least an epoxy resin, a silicone resin, polyester, polyurethane, nano silicate, or nano titanium, and the thickness range of the attachment portion 201 is 0.5˜100 micrometers; and the second thin film portion 301, which is provided with two surfaces, wherein one of the surfaces is partially or completely contiguously attached to the attachment portion 201. The present embodiment has characteristics including the first thin film portion 101, the attachment portion 201, and the second thin film portion 301 are assembled to form the thin encapsulating attachment structure, the thickness of which is less than or equal to 200 micrometers. The first thin film portion 101 is aluminum, copper, nickel, gold, silver, silicon, ceramic, epoxy resin, polyimide, or plastic. A 90-degree peel strength of the attachment portion 201 attached to the first thin film portion 101 and the second thin film portion 301 is ≥4 N/cm. A 180-degree peel strength of the attachment portion 201 attached to the first thin film portion 101 and the second thin film portion 301 is ≥2 N/cm. The second thin film portion 301 is aluminum, copper, nickel, gold, silver, silicon, ceramic, epoxy resin, polyimide, or plastic.

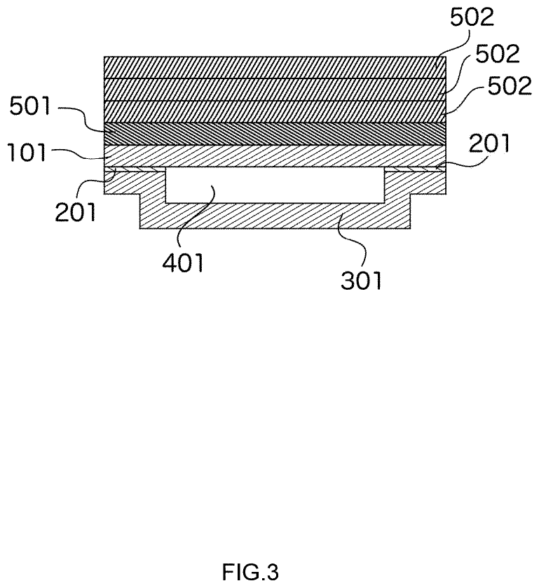

In order for the review committee to further understand the practical applications of the present invention, examples of the application area of the thin encapsulating attachment structure are described below. FIG. 3 is a cross-sectional view of the thin encapsulating attachment structure laminated with a first functional layer 501 and second functional layers 502 according to the present invention. For example, the thin encapsulating attachment structure of FIG. 1 comprises the first thin film portion 101 and the second thin film portion 301, and the outer side surface of the first thin film portion 101 is further covered with at least a first functional layer 501 and at least one layer of the second functional layers 502. The thickness of the first functional layer 501 is less than 200 micrometers; moreover, the lower surface of the first functional layer 501 is laminated adjacent to the upper surface of the first thin film portion 101. The first functional layer 501 is a ceramic material, graphene material, or a binding agent, wherein the binding agent is made from at least an epoxy resin, silicone resin, polyester, polyurethane, nano silicate, or nano titanium. And the thickness of the at least one second functional layer 502 is less than 200 micrometers, and the lower surface of the second functional layer 502 is laminated adjacent to the upper surface of the first functional layer 501. The second functional layer 502 is a ceramic material, graphene material, binding agent, polyimide, polyamide, polyester, polypropylene, polyurethane, copper, aluminum, glue material, or a metal conducting material, wherein the binding agent is composed of at least an epoxy resin, a silicone resin, polyester, polyurethane, nano silicate, or nano titanium. FIG. 3 shows the outer side surface of the first thin film portion 101 covered with one layer of the first functional layer 501 and sequentially laminated with three layers of the second functional layer 502, thereby achieving a single-sided heat conduction effect. The polyamide is a polymer prepared from a monomer containing carboxyl groups and amino groups that have undergone amide chain polymerization. The polypropylene is a high molecular material, repeat units of which are composed of three carbon atoms, wherein two carbon atoms are on the main chain, and one carbon atom exists as a branched chain form.

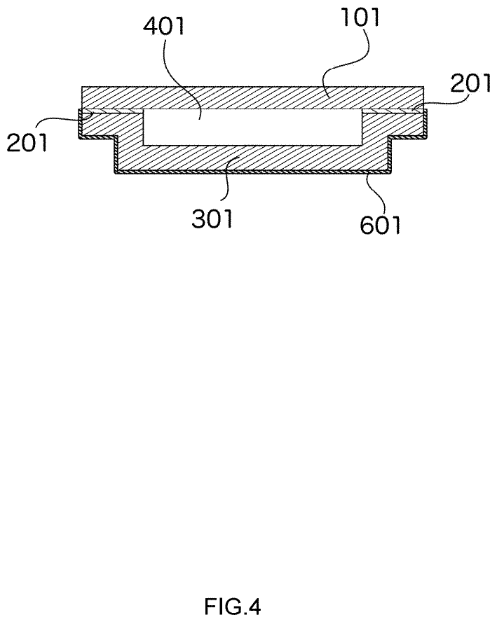

FIG. 4 is a cross-sectional view of a heat dissipation coating deposited on the outer layer of the thin encapsulating attachment structure of the present invention. For example, the thin encapsulating attachment structure of FIG. 1 comprises at least the first thin film portion 101 and the outer side surface of the second thin film portion 301 is further covered with a heat dissipation coating 601, which is at least graphene, graphite flakes, or ceramic. The at least graphene, graphite flakes, or ceramic is deposited on the surface of the thin encapsulating attachment structure surface using a spraying, impregnation or a coating method, to provide radiation heat dissipation and vaporizing functions, as well as further improving the heat dissipation function of the structure. FIG. 4 shows the outer side surface of the second thin film portion 301 covered with the heat dissipation coating 601, which saves on the usage amount of the heat dissipation coating 601 while achieving a single-sided heat dissipation effect, as well as defining characteristics of increasing the heat dissipation area and radiation heat dissipation of the second thin film portion 301.

Summarizing the structure and characteristics of the above-described embodiments, the present utility model provides a thin encapsulating attachment structure comprising:the first thin film portion 101, which is provided with two surfaces, wherein one of the surfaces is partially or completely contiguously attached to the attachment portion 201; the attachment portion 201, which is positioned between the first thin film portion 101 and the second thin film portion 301, wherein the attachment portion 201 is a binding agent composed of at least an epoxy resin, a silicone resin, polyester, polyurethane, nano silicate, or nano titanium, and the thickness range of the attachment portion 201 is 0.5˜100 micrometers; and the second thin film portion 301, which is provided with two surfaces, wherein one of the surfaces is partially or completely contiguously attached to the attachment portion 201. The present invention is provided with characteristics including: the first thin film portion 101, the attachment portion 201, and the second thin film portion 301 are assembled to form the thin encapsulating attachment structure, the thickness of which is less than or equal to 200 micrometers. The first thin film portion 101 is aluminum, copper, nickel, gold, silver, silicon, ceramic, epoxy resin, polyimide, or plastic; the attachment portion 201 attached between the first thin film portion 101 and the second thin film portion 301 has a 90-degree peel strength of 4 N/cm and has a 180-degree peel strength of ≥2 N/cm. The second thin film portion 301 is aluminum, copper, nickel, gold, silver, silicon, ceramic, epoxy resin, polyimide, or plastic, with at least the first thin film portion 101 andthe second thin film portion 301 internally provided with the holding space 401. The holding space 401 is filled with at least gel, wax, hot-melt material, or heat conduction material, wherein the heat conduction material internally contains at least aluminum oxide, aluminium nitride, boron nitride, carborundum, carbon black powder, graphite powder, graphene powder, carbon nanotubes, nano diamond powder, or ceramic powder. The holding space 401 enables holding electronic chip components, to allow covering the electronic chip components. The electronic chip components are attached to the attachment portion 201; moreover, the attachment portion 201 is at least attached to the first thin film portion 101 and the second thin film portion 301. Furthermore, at least the outer side surface of the first thin film portion 101 attached to the second thin film portion 301 of the thin encapsulating attachment structure is covered with at least the first functional layer 501. The thickness of the first functional layer 501 is less than 200 micrometers, and the upper surface of the first thin film portion 101 is laminated adjacent to the lower surface of the first functional layer 501. The first functional layer 501 is a ceramic material, graphene material, or a binding agent, wherein the binding agent is composed of at least an epoxy resin, silicone resin, polyester, polyurethane, nano silicate, or nano titanium; and the thickness of the at least one layer of the second functional layer 502 is less than 200 micrometers. The upper surface of the first functional layer 501 is laminated adjacent to the lower surface of the second functional layer 502. The second functional layer 502 is a ceramic material, graphene material, binding agent, polyimide, polyamide, polyester, polypropylene, polyurethane, copper, aluminum, glue material, or metal conducting material, wherein the binding agent is composed of at least an epoxy resin, a silicone resin, polyester, polyurethane, nano silicate, or nano titanium. Furthermore, the outer side surface of the second thin film portion 301 attached to the at least first thin film portion 101 of the thin encapsulating attachment structure is covered with the heat dissipation coating 601, wherein the heat dissipation coating 601 is at least graphene, graphite flakes, or ceramic. The characteristics of the thin encapsulating attachment structure of the present utility model include the thickness of the thin encapsulating attachment structure is less than or equal to 200 micrometers, and such a thin structure distinguishes and differentiates it from the prior art, providing a solution to heat dissipation of electronic equipment within increasingly small space constraints, thereby characterizing it from the prior art. Hence, the originality, advancement, and practical effectiveness of the present invention are unmistakable, providing effective improvements on the shortcomings of the prior art, and, therefore, has considerable practicability in use.

In conclusion, the concrete structures of the embodiments disclosed in the present invention undoubtedly have application in areas such as electronic component encapsulation, thin heat dissipation plates, and heat dissipation conductive flexible boards. Furthermore, the overall structure of the present invention has not been seen in like products, and the contents of this specification have not been publicly disclosed prior to this application. The practicability and advancement of the present invention clearly comply with the essential elements as required for a new patent application, accordingly, a new patent application is proposed herein.

It is of course to be understood that the embodiments described herein are merely illustrative of the principles of the invention and that a wide variety of modifications thereto may be effected by persons skilled in the art without departing from the spirit and scope of the invention as set forth in the following claims.

What is claimed is:

1. A thin encapsulating attachment structure, comprising:
a first thin film portion, which is provided with two surfaces;
a second thin film portion, which is provided with two surfaces;
an attachment portion, which is positioned between the first thin film portion and the second thin film portion, wherein one of the surfaces of the first thin film portion is partially or completely contiguously attached to the attachment portion, one of the surfaces of the second thin film portion is partially or completely contiguously attached to the attachment portion, the attachment portion is a binding agent composed of at least an epoxy resin, silicone resin, polyester, polyurethane, nano silicate, or nano titanium; moreover, and the thickness range of the attachment portion is 0.5˜100 micrometers;
the first thin film portion, the attachment portion, and the second thin film portion are assembled to form the thin encapsulating attachment structure, the thickness of which is less than or equal to 200 micrometers.

2. The thin encapsulating attachment structure according to claim 1, wherein the first thin film portion is composed of aluminum, copper, nickel, gold, silver, silicon, ceramic, epoxy resin, polyimide, or plastic.

3. The thin encapsulating attachment structure according to claim 1, wherein the attachment portion is composed of at least an epoxy resin, silicone resin, polyester, polyurethane, nano silicate, or nano titanium;
a 90-degree peel strength of the attachment portion attached between the first thin film portion and the second thin film portion is ≥4 N/cm.

4. The thin encapsulating attachment structure according to claim 1, wherein the attachment portion is composed of at least an epoxy resin, silicone resin, polyester, polyurethane, nano silicate, or nano titanium;
a 180-degree peel strength of the attachment portion attached between the first thin film portion and the second thin film portion is ≥2 N/cm.

5. The thin encapsulating attachment structure according to claim 1, wherein the second thin film portion is composed of aluminum, copper, nickel, gold, silver, silicon, ceramic, epoxy resin, polyimide, or plastic.

6. The thin encapsulating attachment structure according to claim 1, wherein at least the first thin film portion and the second thin film portion is internally provided with a holding space.

7. The thin encapsulating attachment structure according to claim 6, wherein the holding space is filled with at least a gel, wax, hot-melt material, or a heat conduction material; the heat conduction material internally contains at least aluminum oxide, aluminium nitride, boron nitride, carborundum, carbon black powder, graphite powder, graphene powder, carbon nanotubes, nano diamond powder, or ceramic powder.

8. The thin encapsulating attachment structure according to claim 6, wherein the holding space enables holding electronic chip components, to enable covering the electronic chip components.

9. The thin encapsulating attachment structure according to claim 1, which further comprises at least the first thin film portion and the second thin film portion, an outer side surface of the first thin film portion is further covered with at least a first functional layer, the thickness of the first functional layer is less than 200 micrometers; moreover, a lower surface of the first functional layer is laminated adjacent to an upper surface of the first thin film portion; the first functional layer is a ceramic material, graphene material, or a binding agent, wherein the binding agent is composed of at least an epoxy resin, silicone resin, polyester, polyurethane, nano silicate, or nano titanium, and at least one layer of the second functional layer, the thickness of which is less than 200 micrometers, a lower surface of the second functional layer is laminated adjacent to an upper surface of the first functional layer, the second functional layer is a ceramic material, graphene material, binding agent, polyimide, polyamide, polyester, polypropylene, polyurethane, copper, aluminum, glue material, or a metal conducting material, wherein the binding agent is composed of at least an epoxy resin, a silicone resin, polyester, polyurethane, nano silicate, or nano titanium.

10. The thin encapsulating attachment structure according to claim 1, which further comprises at least the first thin film portions and the outer side surface of the second thin film portion is further covered with a heat dissipation coating, which is composed of at least graphene, graphite flakes, or ceramic.
